(19) United States
(12) Patent Application Publication
(10) Pub. No.: US 2023/0317422 A1
(43) Pub. Date: Oct. 5, 2023

(54) SUBSTRATE PROCESSING APPARATUS

(71) Applicant: Tokyo Electron Limited, Tokyo (JP)

(72) Inventors: Norinao TAKASU, Miyagi (JP); Shinya YAMANAKA, Miyagi (JP); Yuta TACHIBANA, Miyagi (JP); Takashi KITAZAWA, Miyagi (JP)

(73) Assignee: Tokyo Electron Limited, Tokyo (JP)

(21) Appl. No.: 18/129,437

(22) Filed: Mar. 31, 2023

(30) Foreign Application Priority Data
Mar. 31, 2022 (JP) 2022-061310

(51) Int. Cl. H01J 37/32

(52) U.S. Cl. CPC H01J 37/32449; H01J 37/32724; H01J 2237/002

(57) ABSTRACT

A substrate processing apparatus comprising a plasma processing chamber having a substrate support therein which supports a substrate. A shower head faces the substrate support and includes a shower plate formed with a plurality of gas introduction ports through each of which a gas is discharged. A cooling plate holds the shower plate and is formed with a coolant passage through which a coolant is supplied. A plurality of gas diffusion chambers are formed between the shower plate and the cooling plate, and each of the plurality of gas diffusion chambers communicates with each of a plurality of gas supply flow paths and one or more of the plurality of gas introduction ports, respectively. At least a part of the coolant passage is disposed above a heat transfer surface between the shower plate and the cooling plate, in a plan view.

### CROSS-REFERENCE TO RELATED APPLICATIONS

This application claims priority to Japanese Patent Application No. 2022-061310, filed on Mar. 31, 2022, the entire contents of which are incorporated herein by reference.

### TECHNICAL FIELD

The present disclosure relates to a substrate processing apparatus.

### BACKGROUND

Patent Document 1 discloses an apparatus that includes a shower head disposed to face a substrate disposed on an upper surface of a stage, in which the shower head includes a surface plate having a plurality of holes, an intermediate plate having a gas flow path and a heater for heating a gas, and a top plate thermally connected to the intermediate plate.

Patent Document 2 discloses a shower head electrode assembly that includes an upper electrode formed with a gas flow path, a backing member having a plenum formed on a lower surface thereof, and a thermal control plate.

### PRIOR ART DOCUMENTS

### Patent Documents

Patent Document 1: US2011/0180233A
Patent Document 2: US2008/0141941A

### SUMMARY

In one aspect, the present disclosure provides a substrate processing apparatus that includes a shower head having a shower plate and a cooling plate, in which a warpage of the cooling plate is suppressed and damage to the shower plate is prevented or reduced.

In order to solve the above-described problem, according to one aspect, there is provided a substrate processing apparatus comprising: a plasma processing chamber; a substrate support that is provided in the plasma processing chamber and supports a substrate; and a shower head facing the substrate support, the shower head including: a shower plate formed with a plurality of gas introduction ports through each of which a gas is discharged; a cooling plate holding the shower plate and formed with a coolant passage through which a coolant is supplied and a plurality of gas supply flow paths; and a plurality of gas diffusion chambers formed between the shower plate and the cooling plate, each of the plurality of gas diffusion chambers communicating with each of the plurality of gas supply flow paths and each one or more of the plurality of gas introduction ports, respectively, in which at least a part of the coolant passage is disposed above a heat transfer surface between the shower plate and the cooling plate, in a plan view.

With one aspect, it is possible to provide a substrate processing apparatus that includes a shower head having a shower plate and a cooling plate, in which a warpage of the cooling plate is suppressed and damage to the shower plate is prevented or reduced.

### BRIEF DESCRIPTION OF THE DRAWINGS

FIG. 1 is an example of a diagram illustrating a configuration example of a capacitively-coupled substrate processing apparatus.

FIG. 2 is an example of a cross-sectional view of a shower head according to a first embodiment.

FIG. 3 is an example of a bottom view of a cooling plate according to the first embodiment, when viewed from a downward direction.

FIG. 4 is an example of a cross-sectional view of a shower head according to a second embodiment.

FIG. 5 is an example of a bottom view of a cooling plate according to the second embodiment, when viewed from the downward direction.

FIG. 6 is an example of a cross-sectional view of a shower head according to a third embodiment.

### DETAILED DESCRIPTION

Various exemplary embodiments are described below in detail with reference to the drawings. Further, like reference numerals are given to like or corresponding parts throughout the drawings.

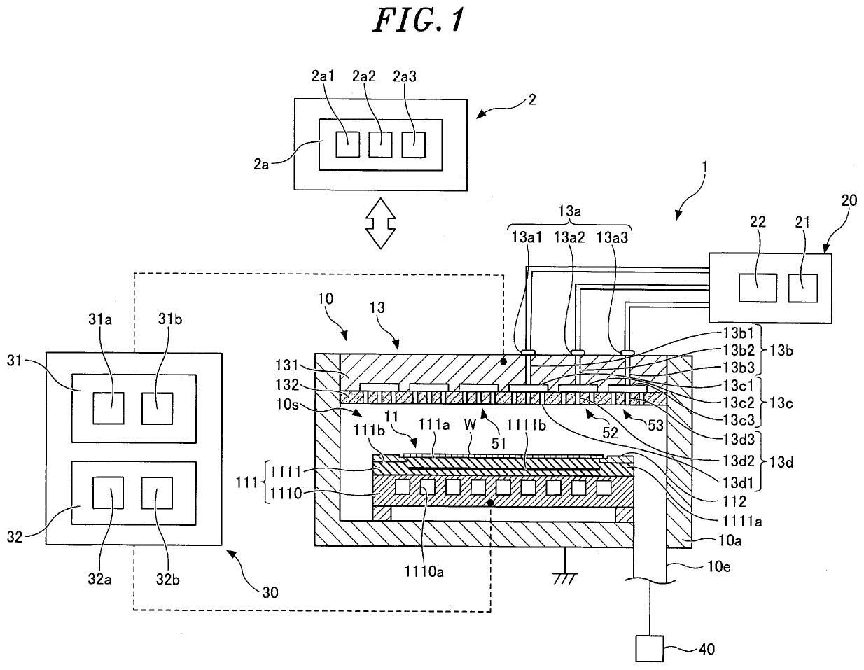

An example of a configuration example of a plasma processing system are described below. FIG. 1 is an example of a diagram illustrating a configuration example of a capacitively-coupled substrate processing apparatus.

The plasma processing system comprises a capacitively-coupled substrate processing apparatus 1 and a controller 2. The capacitively-coupled substrate processing apparatus 1 includes a plasma processing chamber 10, a gas supply 20, a power source 30, and an exhaust system 40. Further, the substrate processing apparatus 1 includes a substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 has at least one gas supply port for supplying at least one processing gas into the plasma processing space 10s, and at least one gas exhaust port for exhausting the gas from the plasma processing space 10s. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is disposed on the central region 111a of the main body 111 and the ring assembly 112 is disposed on the annular region 111b of the main body 111 to surround the substrate W on the central region 111a of the main body 111. Accordingly, the central region 111a is also referred to as a substrate support surface for supporting the substrate W, and the annular region 111b is also referred to as a ring support surface for supporting the ring assembly 112.

In one embodiment, the main body 111 includes a base 1110 and an electrostatic chuck 1111. The base 1110 includes a conductive member. The conductive member of the base 1110 functions as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In one embodiment, the ceramic member 1111a also has the annular region 111b. Other members that surround the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one RF/DC electrode coupled to a radio frequency (RF) power source 31 and/or a direct current (DC) power source 32 to be described below may be disposed inside the ceramic member 1111a. In this case, at least one RF/DC electrode functions as the lower electrode. In a case where a bias RF signal and/or a DC signal to be described below are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Accordingly, the substrate support 11 includes at least one lower electrode.

The ring assembly 112 includes one or more annular members. In one embodiment, one or more annular members include one or more edge rings and at least one cover ring. The edge ring is formed of a conductive material or an insulating material, and the cover ring is formed of an insulating material.

Further, the substrate support 11 may include a temperature control module configured to adjust at least one of the electrostatic chuck 1111, the ring assembly 112, and the substrate to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed inside the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The shower head 13 is configured to introduce at least one processing gas from the gas supply 20 into the plasma processing space 10s. The shower head 13 has at least one gas supply port 13a (13a1 to 13a3), at least one gas supply flow path 13b (13b1 to 13b3), at least one gas diffusion chamber 13c (13c1 to 13c3), and a plurality of gas introduction ports 13d (13d1 to 13d3). The processing gas supplied to the gas supply port 13a passes through the gas supply flow path 13b and the gas diffusion chamber 13c, and is introduced into the plasma processing space 10s from the plurality of gas introduction ports 13d.

Further, the shower head 13 illustrated in FIG. 1 includes a gas introduction portion 51, a gas introduction portion 52, and a gas introduction portion 53. The gas introduction portion 51 introduces a gas into a central region (center region) of the substrate W in the plasma processing chamber 10. The gas introduction portion 52 introduces a gas into a region (intermediate region) outside the gas introduction portion 51. The gas introduction portion 53 introduces a gas into a region (edge region) outside the gas introduction portion 52. The gas introduction portion 51, the gas introduction portion 52, and the gas introduction portion 53 are concentrically disposed.

The gas supply port 13a has the gas supply port 13a1, the gas supply port 13a2, and the gas supply port 13a3. A gas to be introduced into the gas introduction portion 51 is supplied to the gas supply port 13a1. A gas to be introduced into the gas introduction portion 52 is supplied to the gas supply port 13a2. A gas to be introduced into the gas introduction portion 53 is supplied to the gas supply port 13a3.

The gas supply flow path 13b has the gas supply flow path 13b1, the gas supply flow path 13b2, and the gas supply flow path 13b3. The gas supply flow path 13b1 connects the gas supply port 13a1 and the gas diffusion chamber 13c1. The gas supply flow path 13b2 connects the gas supply port 13a2 and the gas diffusion chamber 13c2. The gas supply flow path 13b3 connects the gas supply port 13a3 and the gas diffusion chamber 13c3.

The gas diffusion chamber 13c has the gas diffusion chamber 13c1, the gas diffusion chamber 13c2, and the gas diffusion chamber 13c3. The gas supply flow path 13b1 and a plurality of gas introduction ports 13d1 are connected to the gas diffusion chamber 13c1 so as to allow the gas to flow therethrough. The gas introduction portion 51 has the gas supply port 13a1, the gas supply flow path 13b1, the gas diffusion chamber 13c1, and the plurality of gas introduction ports 13d1. Further, the gas supply flow path 13b2 and a plurality of gas introduction ports 13d2 are connected to the gas diffusion chamber 13c2 so as to allow the gas to flow therethrough. The gas introduction portion 52 has the gas supply port 13a2, the gas supply flow path 13b2, the gas diffusion chamber 13c2, and the plurality of gas introduction ports 13d2. Further, the gas supply flow path 13b3 and a plurality of gas introduction ports 13d3 are connected to the gas diffusion chamber 13c3 so as to allow the gas to flow therethrough. The gas introduction portion 53 has the gas supply port 13a3, the gas supply flow path 13b3, the gas diffusion chamber 13c3, and the plurality of gas introduction ports 13d3.

Further, the shower head 13 includes at least one upper electrode. The gas introduction unit may include, in addition to the shower head 13, one or a plurality of side gas injectors (SGI) that are attached to one or a plurality of openings formed in the sidewall 10a.

Further, the shower head 13 includes a cooling plate 131 and a shower plate 132. The cooling plate 131 holds the shower plate 132. Further, the cooling plate 131 has a function of cooling the held shower plate 132. In addition, the gas supply port 13a, the gas supply flow path 13b, and the gas diffusion chamber 13c are formed at the cooling plate 131. The cooling plate 131 is formed of, for example, Al, SiC, or metal matrix composites (MMC).

The plurality of gas introduction ports 13d are formed in the shower plate 132. When the shower plate 132 is held on the cooling plate 131, the plurality of gas introduction ports 13d communicate with the gas diffusion chamber 13c. The shower plate 132 is formed of, for example, Si, SiC, SiO₂, Al, or the like.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes the RF power source 31 coupled to the plasma processing chamber 10 via at least one impedance matching circuit. The RF power source 31 is configured to supply at least one RF signal (RF power) to at least one lower electrode and/or at least one upper electrode. Accordingly, a plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, supplying the bias RF signal to at least one lower electrode can generate a bias potential in the substrate W to attract an ionic component in the formed plasma to the substrate W.

In one embodiment, the RF power source 31 includes a first RF generator 31a and a second RF generator 31b. The first RF generator 31a is configured to be coupled to at least one lower electrode and/or at least one upper electrode via at least one impedance matching circuit to generate a source RF signal (source RF power) for plasma generation. In one embodiment, the source RF signal has a frequency in the range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is configured to be coupled to at least one lower electrode via at least one impedance matching circuit to generate the bias RF signal (bias RF power). A frequency of the bias RF signal may be the same as or different from a frequency of the source RF signal. In one embodiment, the bias RF signal has a lower frequency than the frequency of the source RF signal. In one embodiment, the bias RF signal has a frequency in the range of 100 kHz to 60 MHz. In one embodiment, the second RF generator 31b may be configured to generate a plurality of bias RF signals having different frequencies. The generated one or more bias RF signals are supplied to at least one lower electrode. In addition, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to at least one lower electrode to generate the first DC signal. The generated first bias DC signal is applied to at least one lower electrode. In one embodiment, the second DC generator 32b is configured to be connected to at least one upper electrode to generate a second DC signal. The generated second DC signal is applied to at least one upper electrode.

In various embodiments, at least one of the first and second DC signals may be pulsed. In this case, a sequence of voltage pulses is applied to at least one lower electrode and/or at least one upper electrode. The voltage pulse may have a pulse waveform of a rectangle, a trapezoid, a triangle, or a combination thereof. In one embodiment, a waveform generator for generating a sequence of voltage pulses from the DC signal is connected between the first DC generator 32a and at least one lower electrode. Accordingly, a voltage pulse generator is configured with the first DC generator 32a and the waveform generator. In a case where the voltage pulse generator is configured with the second DC generator 32b and the waveform generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the substrate processing apparatus 1 to execute various steps described in the present disclosure. The controller 2 may be configured to control each element of the substrate processing apparatus 1 to execute the various steps described herein below. In an embodiment, part or all of the controller 2 may be included in the substrate processing apparatus 1. The controller 2 may include a processor 2a1, a storage unit 2a2, and a communication interface 2a3. The controller 2 is implemented by, for example, a computer 2a. The processor 2a1 may be configured to read a program from the storage unit 2a2 and perform various control operations by executing the read program. The program may be stored in advance in the storage unit 2a2, or may be acquired via a medium when necessary. The acquired program is stored in the storage unit 2a2, and is read from the storage unit 2a2 and executed by the processor 2a1. The medium may be various storing media readable by the computer 2a, or may be a communication line connected to the communication interface 2a3. The processor 2a1 may be a Central Processing Unit (CPU). The storage unit 2a2 may include a random access memory (RAM), a read only memory (ROM), a hard disk drive (HDD), a solid state drive (SSD), or a combination thereof. The communication interface 2a3 may communicate with the substrate processing apparatus 1 via a communication line such as a local area network (LAN).

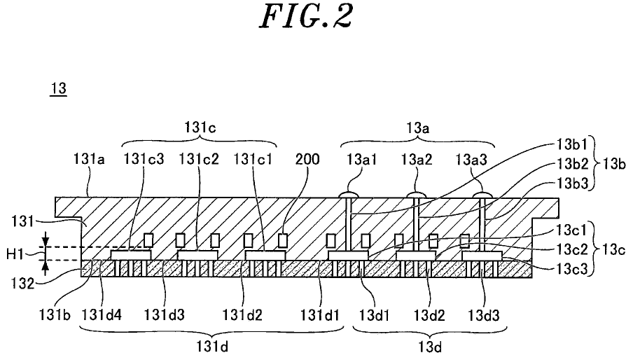

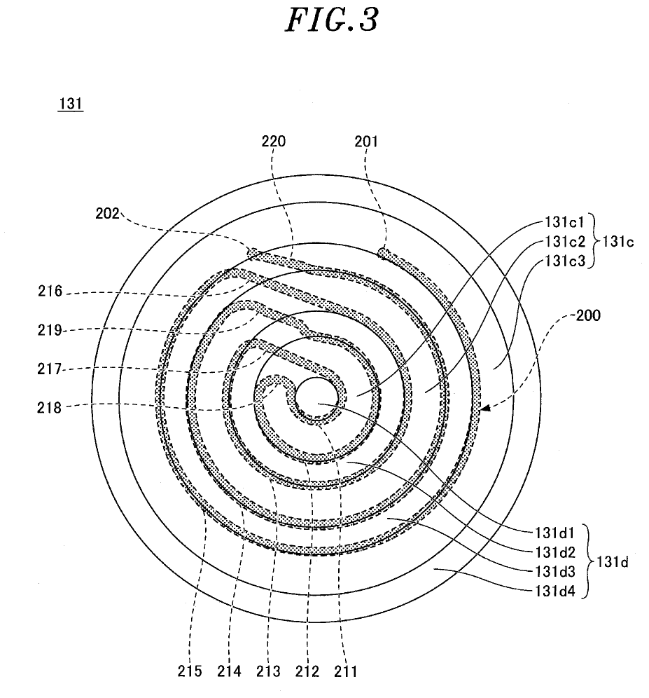

Next, the shower head 13 will be described with reference to FIGS. 2 to 3. FIG. 2 is an example of a cross-sectional view of the shower head 13 according to a first embodiment. FIG. 3 is an example of a bottom view of the cooling plate 131 according to the first embodiment, when viewed from a downward direction. In FIG. 3, a coolant passage 200 is illustrated by a broken line, and the coolant passage 200 is clearly illustrated by attaching a pattern of dots thereto.

The gas supply port 13a (13a1 to 13a3) is provided at an upper surface 131a of the cooling plate 131. Further, the cooling plate 131 is provided with the gas supply flow path 13b (13b1 to 13b3) which are flow paths passing through the cooling plate 131 in a plate thickness direction. The gas supply flow path 13b (13b1 to 13b3) is formed to communicate with the gas supply port 13a (13a1 to 13a3) and a recessed groove 131c (131c1 to 131c3), respectively. The recessed groove 131c (131c1 to 131c3) is formed at a lower surface 131b of the cooling plate 131. The recessed groove 131c is formed in, for example, an annular shape concentric with the cooling plate 131. In the example illustrated in FIG. 3, the recessed groove 131c1 is formed as a recessed groove having an annular shape. The recessed groove 131c2 is formed as a recessed groove having an annular shape, disposed on an outer peripheral side of the recessed groove 131c1. The recessed groove 131c3 is formed as a recessed groove having an annular shape, disposed on an outer peripheral side of the recessed groove 131c2.

The shape of the recessed groove 131c (131c1 to 131c3) is described as being formed in an annular shape. Meanwhile, the present embodiment is not limited thereto. For example, the recessed groove 131c1 may be formed as a recessed groove having a circular shape. Further, the recessed groove 131c2 may be formed as a recessed groove having an annular shape, disposed on an outer peripheral side of the recessed groove 131c1, and the recessed groove 131c3 may be formed as a recessed groove having an annular shape, disposed on an outer peripheral side of the recessed groove 131c2.

The gas diffusion chamber 13c1 is formed with the recessed groove 131c1 formed at the lower surface 131b of the cooling plate 131 and an upper surface of the shower plate 132. In the same manner, the gas diffusion chamber 13c2 is formed with the recessed groove 131c2 formed in the lower surface 131b of the cooling plate 131 and the upper surface of the shower plate 132. Further, the gas diffusion chamber 13c3 is formed with the recessed groove 131c3 formed in the lower surface 131b of the cooling plate 131 and the upper surface of the shower plate 132.

With this configuration, the processing gas supplied from the gas supply port 13a is supplied to the gas diffusion chamber 13c via the gas supply flow path 13b. The processing gas diffused in the gas diffusion chamber 13c is discharged into the plasma processing space 10s (see FIG. 1) via the gas introduction port 13d. With this configuration, a supply pressure of the processing gas may be reduced in the gas diffusion chamber 13c. Accordingly, it is possible to suppress an abnormal discharge that occurs between the cooling plate 131 and the shower plate 132.

Further, the lower surface 131b of the cooling plate 131 has a heat transfer surface 131d (131d1 to 131d4) which transfers heat between the cooling plate 131 and the shower plate 132 by abutting onto the shower plate 132. In the example illustrated in FIG. 3, the heat transfer surface 131d1 is formed in a circular shape, and formed inside the recessed groove 131c1. The heat transfer surface 131d2 is formed in an annular shape, and formed outside the recessed groove 131c1 and inside the recessed groove 131c2. The heat transfer surface 131d3 is formed in an annular shape, and formed outside the recessed groove 131c2 and inside the recessed groove 131c3. The heat transfer surface 131d4 is formed in an annular shape, and formed outside the recessed groove 131c3. With this configuration, the cooling plate 131 is in contact with the shower plate 132 at the heat transfer surface 131d (131d1 to 131d4), and is not in contact with the shower plate 132 in a region in which the recessed groove 131c (131c1 to 131c3) is formed.

The shape of the heat transfer surface 131d (131d1 to 131d4) is not limited thereto. For example, in a case where the recessed groove 131c1 is formed as a recessed groove having a circular shape, the heat transfer surface 131d1 formed in a circular shape may not be provided.

Further, in a region in which the heat transfer surface 131d (131d1 to 131d4) is formed, a bolt hole (not illustrated) for inserting a bolt (not illustrated) for fastening the cooling plate 131 and the shower plate 132 may be formed. Accordingly, the shower plate 132 is detachably attached to the cooling plate 131. The method of attaching the shower plate 132 on the cooling plate 131 is not limited thereto. For example, the cooling plate 131 and the shower plate 132 may be configured to be clamped by a clamp member (not illustrated) at an outer peripheral portion of the shower plate 132.

In other words, the heat transfer surface 131d (131d1 to 131d4) and the recessed groove 131c (131c1 to 131c3) are alternately and repeatedly formed on the lower surface 131b of the cooling plate 131 from a center of the cooling plate 131 toward an outer periphery of the cooling plate 131. Further, the coolant passage 200 through which a coolant such as brine flows is formed in the cooling plate 131. A coolant supply path 201 is formed at one end of the coolant passage 200, and a coolant exhaust path 202 is formed at the other end of the coolant passage 200. The coolant supply path 201 is a flow path formed from the upper surface 131a of the cooling plate 131 in a height direction of the cooling plate 131, and connected to the one end of the coolant passage 200. The coolant exhaust path 202 is a flow path formed from the upper surface 131a of the cooling plate 131 in the height direction of the cooling plate 131, and connected to the other end of the coolant passage 200. The coolant supply path 201 and the coolant exhaust path 202 are connected to a coolant supply device (not illustrated) such as a chiller. Accordingly, a coolant supplied from the coolant supply device to the coolant supply path 201 flows through the coolant passage 200 in the cooling plate 131 and exhausts the heat from the cooling plate 131, and the coolant is exhausted from the coolant exhaust path 202.

Here, as illustrated in FIG. 2, in the height direction, the coolant passage 200 is preferably formed such that a height H1 from the heat transfer surface 131d of the cooling plate 131 to a lower surface of the coolant passage 200 is in a range equal to or more than 3 mm and equal to or less than 20 mm. Accordingly, the coolant passage 200 can be brought close to the heat transfer surface 131d.

Further, as illustrated in FIG. 3, in a plan view, the coolant passage 200 is disposed in the vicinity of the heat transfer surface 131d of the cooling plate 131. Specifically, in a plan view, the coolant passage 200 is disposed such that at least a part of the coolant passage 200 is disposed on the heat transfer surface 131d of the cooling plate 131.

More specifically, as illustrated in FIG. 3, the coolant passage 200 has partial coolant passages 211 to 220.

In the plan view, the coolant passage 200 has the partial coolant passage 211 disposed along a boundary between an outer periphery of the heat transfer surface 131d1 and an inner periphery of the recessed groove 131c1 (the gas diffusion chamber 13c1). In the plan view, the partial coolant passage 211 is formed in an arc shape, and at least a part thereof is formed on the heat transfer surface 131d1.

In the plan view, the coolant passage 200 has the partial coolant passage 212 disposed along a boundary between an outer periphery of the recessed groove 131c1 (the gas diffusion chamber 13c1) and an inner periphery of the heat transfer surface 131d2. In the plan view, the partial coolant passage 212 is formed in an arc shape, and at least a part thereof is formed on the heat transfer surface 131d2.

In the plan view, the coolant passage 200 has the partial coolant passage 213 disposed along a boundary between an outer periphery of the heat transfer surface 131d2 and an inner periphery of the recessed groove 131c2 (the gas diffusion chamber 13c2). In the plan view, the partial coolant passage 213 is formed in an arc shape, and at least a part thereof is formed on the heat transfer surface 131d2.

In the plan view, the coolant passage 200 has the partial coolant passage 214 disposed along a boundary between an outer periphery of the recessed groove 131c2 (the gas diffusion chamber 13c2) and an inner periphery of the heat transfer surface 131d3. In the plan view, the partial coolant passage 214 is formed in an arc shape, and at least a part thereof is formed on the heat transfer surface 131d3.

In the plan view, the coolant passage 200 has the partial coolant passage 215 disposed along a boundary between an outer periphery of the heat transfer surface 131d3 and an inner periphery of the recessed groove 131c3 (the gas diffusion chamber 13c3). In the plan view, the partial coolant passage 215 is formed in an arc shape, and at least a part thereof is formed on the heat transfer surface 131d3.

The coolant passage 200 has the partial coolant passage 216 that connects the partial coolant passage 215 and the partial coolant passage 213. Further, the coolant passage 200 has the partial coolant passage 217 that connects the partial coolant passage 213 and the partial coolant passage 211. Further, the coolant passage 200 has the partial coolant passage 218 that connects the partial coolant passage 211 and the partial coolant passage 212. Further, the coolant passage 200 has the partial coolant passage 219 that connects the partial coolant passage 212 and the partial coolant passage 214. Further, the coolant passage 200 has the partial coolant passage 220 that connects the partial coolant passage 214 and the coolant exhaust path 202.

As described above, the coolant supplied from the coolant supply path 201 flows in the order of the partial coolant passage 215 in an arc shape, the partial coolant passage 216, the partial coolant passage 213 in an arc shape, the partial coolant passage 217, the partial coolant passage 211 in an arc shape, the partial coolant passage 218, the partial coolant passage 212 in an arc shape, the partial coolant passage 219, the partial coolant passage 214 in an arc shape, and the partial coolant passage 220, and is exhausted from the coolant exhaust path 202.

In other words, the coolant passage 200 has the partial coolant passage 211 disposed in the vicinity of the heat transfer surface 131d1 having a circular shape so as to cool the heat transfer surface 131d1. Further, the coolant passage 200 has the partial coolant passages 212 and 213 disposed in the vicinity of the heat transfer surface 131d2 having an annular shape so as to cool the heat transfer surface 131d2. Further, the coolant passage 200 has partial coolant passages 214 and 215 disposed in the vicinity of the heat transfer surface 131d3 having an annular shape so as to cool the heat transfer surface 131d3.

Here, a heat input from the plasma formed in the plasma processing space 10s (see FIG. 1) into the shower plate 132 enters the cooling plate 131. Therefore, a temperature of the cooling plate 131 is higher on the lower surface 131b side than on the upper surface 131a side. Accordingly, regarding the cooling plate 131, thermal expansion of the lower surface 131b becomes larger than thermal expansion of the upper surface 131a, and the cooling plate 131 is deformed (warped). Due to the deformation of the cooling plate 131, the shower plate 132 held by the cooling plate 131 may be damaged such as a breakage.

In contrast, as illustrated in FIGS. 2 and 3, the cooling plate 131 is in contact with the shower plate 132 at the heat transfer surface 131d (131d1 to 131d4). That is, a region, in which the recessed groove 131c (131c1 to 131c3) is formed, of the cooling plate 131 is not in contact with the shower plate 132. In this manner, by limiting the contact between the cooling plate 131 and the shower plate 132 by the heat transfer surface 131d, it is possible to reduce the deformation (warpage) of the cooling plate 131 and reduce a load acting on the cooling plate 131, as compared with a configuration in which the cooling plate 131 and the shower plate 132 are in contact with each other on the entire surface. Accordingly, it is possible to prevent or reduce damage such as a breakage of the shower plate 132 held by the cooling plate 131.

Further, the coolant passage 200 is disposed in the vicinity of the heat transfer surface 131d. Accordingly, the heat input to the cooling plate 131 via the heat transfer surface 131d is exhausted by the coolant flowing through the coolant passage 200. Accordingly, it is possible to reduce a temperature difference between the upper surface 131a side and the lower surface 131b side of the cooling plate 131, and suppress the deformation (warpage) of the cooling plate 131. Further, it is possible to prevent or reduce damage such as a breakage of the shower plate 132 held by the cooling plate 131.

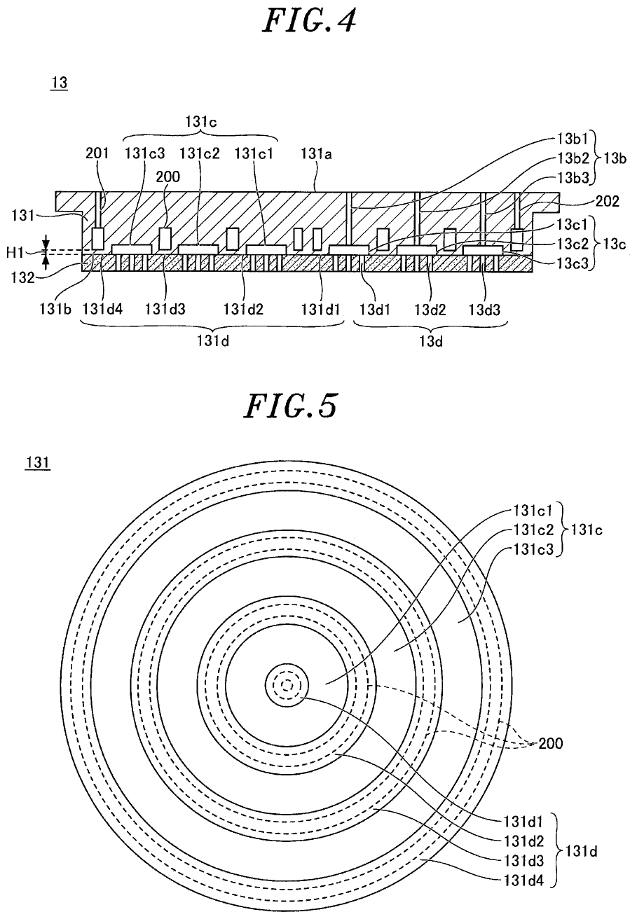

Next, another shower head 13 will be described with reference to FIGS. 4 and 5. FIG. 4 is an example of a cross-sectional view of the shower head 13 according to a second embodiment. FIG. 5 is an example of a bottom view of the cooling plate 131 according to the second embodiment, when viewed from the downward direction.

As illustrated in FIGS. 4 and 5, the coolant passage 200 may be disposed immediately above the heat transfer surface 131d. Specifically, a bottom surface of the coolant passage 200 disposed immediately above the heat transfer surface 131d is disposed at a position lower than a ceiling surface of the recessed groove 131c (the gas diffusion chamber 13c). In other words, the height H1 from the heat transfer surface 131d of the cooling plate 131 to a lower surface of the coolant passage 200 is preferably formed to be lower than a depth of the recessed groove 131c (a height from the heat transfer surface 131d of the cooling plate 131 to the ceiling surface of the recessed groove 131c). It is possible to improve cooling efficiency by the coolant passage 200 being disposed immediately above the heat transfer surface 131d.

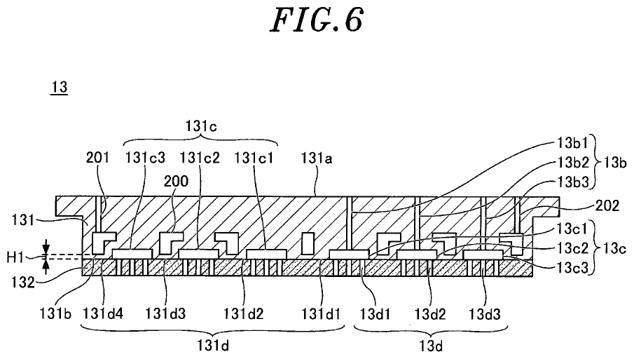

Next, still another shower head 13 will be described with reference to FIG. 6. FIG. 6 is an example of a cross-sectional view of the shower head 13 according to a third embodiment.

As illustrated in FIG. 6, a cross-sectional shape of the coolant passage 200 may be substantially L-shaped in a cross-sectional view to surround the gas diffusion chamber 13c. Accordingly, it is possible to improve the cooling efficiency, by increasing a flow path cross-sectional area of the coolant passage 200 and increasing a flow rate of the coolant.

Although embodiments and the like of a plasma processing system are described above, the present disclosure is not limited to the above-described embodiments and the like, and various modifications and improvements are possible within the scope of the present disclosure described in the claims.

1. A substrate processing apparatus comprising:
a plasma processing chamber;
a substrate support that is provided in the plasma processing chamber and supports a substrate; and
a shower head facing the substrate support,
the shower head including:
a shower plate formed with a plurality of gas introduction ports through each of which a gas is discharged;
a cooling plate holding the shower plate and formed with a coolant passage through which a coolant is supplied and a plurality of gas supply flow paths; and
a plurality of gas diffusion chambers formed between the shower plate and the cooling plate, each of the plurality of gas diffusion chambers communicating with each of the plurality of gas supply flow paths and each one or more of the plurality of gas introduction ports, respectively,
wherein at least a part of the coolant passage is disposed above a heat transfer surface between the shower plate and the cooling plate, in a plan view.

2. The substrate processing apparatus according to claim 1,
wherein each gas diffusion chamber is formed with an upper surface of the shower plate and a recessed groove formed on a lower surface of the cooling plate, and
the one or more of the plurality of gas introduction ports of the shower plate communicate with each of the plurality of gas diffusion chambers.

3. The substrate processing apparatus according to claim 1,
wherein a height from the heat transfer surface of the cooling plate in contact with the shower plate to a lower surface of the coolant passage is equal to or more than 3 mm and equal to or less than 20 mm.

4. The substrate processing apparatus according to claim 2,
wherein a height from the heat transfer surface of the cooling plate in contact with the shower plate to a lower surface of the coolant passage is equal to or more than 3 mm and equal to or less than 20 mm.

5. The substrate processing apparatus according to claim 1,
wherein the coolant passage includes a partial coolant passage disposed along a boundary between the gas diffusion chamber and the heat transfer surface, in the plan view.

6. The substrate processing apparatus according to claim 2,
wherein the coolant passage includes a partial coolant passage disposed along a boundary between the gas diffusion chamber and the heat transfer surface, in the plan view.

7. The substrate processing apparatus according to claim 1,
wherein the coolant passage is disposed immediately above the heat transfer surface, in the plan view.

8. The substrate processing apparatus according to claim 2,
wherein the coolant passage is disposed immediately above the heat transfer surface, in the plan view.

9. The substrate processing apparatus according to claim 7,
wherein a bottom surface of the coolant passage is disposed at a position lower than a ceiling surface of the gas diffusion chamber.

10. The substrate processing apparatus according to claim 8,
wherein a bottom surface of the coolant passage is disposed at a position lower than a ceiling surface of the gas diffusion chamber.

11. The substrate processing apparatus according to claim 1,
wherein the coolant passage is disposed to surround at least part of the plurality of the gas diffusion chambers.

12. The substrate processing apparatus according to claim 2,
wherein the coolant passage is disposed to surround at least part of the plurality of the gas diffusion chambers.

13. The substrate processing apparatus according to claim 1,
wherein the shower plate is formed of any one of Si, SiC, SiO₂, and Al, and
the cooling plate is formed of any one of Al, SiC, or metal matrix composites.

14. The substrate processing apparatus according to claim 2,
wherein the shower plate is formed of any one of Si, SiC, SiO₂, and Al, and
the cooling plate is formed of any one of Al, SiC, or metal matrix composites.
